(19) United States
(12) Patent Application Publication
(10) Pub. No.: US 2024/0417884 A1
(43) Pub. Date: Dec. 19, 2024

(54) CVD SINGLE CRYSTAL DIAMOND

(71) Applicant: Element Six Technologies Limited, Didcot, Oxfordshire (GB)

(72) Inventors: Benjamin Simon TRUSCOTT, Didcot, Oxfordshire (GB); Stephanie LIGGINS, Didcot, Oxfordshire (GB); Daniel James TWITCHEN, Didcot, Oxfordshire (GB); Douglas John GEEKIE, Didcot, Oxfordshire (GB); William Joseph HILLMAN, Didcot, Oxfordshire (GB)

(21) Appl. No.: 18/701,674

(22) PCT Filed: Oct. 19, 2022
(86) PCT No.: PCT/EP2022/079139

§ 371 Date: Apr. 16, 2024

(30) Foreign Application Priority Data
Oct. 19, 2021 (GB) 2114933.1

(51) Int. Cl. C30B 29/04; C30B 25/16; C30B 25/20; C30B 33/02

(52) U.S. Cl. CPC C30B 29/04; C30B 25/165; C30B 25/20; C30B 33/02

(57) ABSTRACT

A CVD single crystal diamond having a smallest linear dimension of no less than 3.5 mm, a concentration of single substitutional nitrogen atoms in their neutral charge state (Nₛ0), as measured by EPR, of between 20 and 250 ppb, a hue angle, hab, between 75 and 135°.

### FIELD OF THE INVENTION

This invention relates to CVD single crystal diamond, and methods of making CVD single crystal diamond.

### BACKGROUND

Interest in the chemical vapour deposition (CVD) synthesis of diamond began in the 1980s, and research by various groups around the world continues to the present day. Most of the published work on single crystal CVD diamond material has disclosed growth of thin (<1 mm) layers via homoepitaxial growth on single crystal diamond substrates, predominantly using microwave plasma CVD. Successful synthesis of thick, high quality layers of single crystal CVD diamond material depends on the stable maintenance of physically extreme process conditions over periods of many days, typically requiring highly specialized synthesis hardware.

Synthesis parameters of importance to single crystal CVD diamond growth include substrate type (for example, whether it be produced by CVD, high-pressure/high-temperature, or natural geological synthesis), the method of substrate preparation from the original host crystal, substrate geometry (including crystallographic orientation of the faces and/or edges), substrate temperature during growth and thermal management of growing crystals, and the gas-phase synthesis environment itself. The latter is influenced by the process gas composition (including impurities), gas pressure within the process chamber, and amount of microwave power supplied for the synthesis process, in addition to various hardware-dependent factors such as the size of the process chamber, process gas inlet/outlet geometry, and process gas flow rate. Many of these parameters are interrelated such that if one parameter is changed then others must also be changed in the correct manner in order to remain in an appropriate growth regime. Failure to select and maintain suitable process conditions over the full deposition area for the entire duration of the synthesis process can result in a high level of uncontrolled process variability, unusable product with inappropriate material properties, or even complete destruction of the crystals by catastrophic cracking, twinning, or graphitization.

Diamond has high thermal conductivity, wide transparency, low dielectric loss, hardness, and other well-known properties. These characteristics, alone or in combination, make it valuable in numerous scientific and technical applications. Synthetic diamond material can be engineered to possess advantageous properties, and examples of applications for which it is uniquely suited are known in the art. Advancing technology has improved the availability of synthetic diamond, which can now be found in some consumer applications as well as increasingly many technical ones such as mechanical wear elements and optical elements.

One such application that has gained prominence in recent years is the use of synthetic diamond gems in jewellery. For polished goods of a given quality, the market price is largely determined by the size (mass) of the gem, and the maximum mass obtainable in a given shape is in turn determined by the minimum linear dimension of the parent crystal, which for CVD crystals is commonly the thickness (as opposed to the width or depth). For example, the round brilliant (RB) gem shape typically requires a minimum dimension of around 4 mm to produce a 1 carat (1 ct) part, while about 5.5 mm is required for a 2 ct RB, both assuming no constraint in the other dimensions. One aspect that is used to distinguish diamond gems of higher versus lower quality is their colour, to the extent that diamonds are sometimes assigned a colour “grade” prior to being marketed to consumers. Such a grade is related to the magnitude of optical absorption exhibited by a given gem. The industry-standard Gemological Institute of America (GIA) colour grades D, E, and F constitute the “colourless” category, while grades and G, H, I, and J are considered “near-colourless”. To date it has been a challenge to reproducibly produce diamonds of large size in the colourless and/or near-colourless brackets.

For certain optical applications, it is desirable to provide a material which has low optical absorbance, and which may be assigned a “colourless” grade of D, E, or F when polished as a gem. Such a material can constitute a single crystal CVD synthetic diamond material which has a low concentration of impurities, which would otherwise increase the optical absorbance of the material. The converse could also apply: material suitable for colourless gems may possess properties that are desirable as well for certain optical applications. Patent literature relevant to such optical grade single crystal CVD synthetic diamond material and its applications includes WO2004/046427 and WO2007/066215.

Diamond gem colour is characterized not only by its intensity, but also the hue: for example, yellow, brown, pink, blue, and so on. Brown diamonds or those with a noticeable brown component to their hue (for instance, brownish yellow) are typically less desired for jewellery. Pink and blue hued diamonds that have a similar intensity of colour to yellow and/or brown diamonds in the near-colourless category are typically graded as “fancy light” rather than near-colourless, and a letter grade is not currently given by the GIA for such samples. While individual preferences vary, the most widely accepted hue in colourless to near-colourless diamonds is yellow.

CVD synthetic diamond material typically takes on a brownish hue during growth, which can be changed to hues including pinkish brown, pinkish orange, pink, orangey pink, or yellow through optional post-growth heat treatment. As explained in WO2004/022821, such heat treatment is preferably performed at temperatures exceeding 1400° C. if a hue change is to be accomplished within a practical amount of time for an industrial process. It is further taught that at temperatures exceeding 1600° C., as may be required to produce particular hues, the rate of graphitization can be significant unless diamond-stabilizing pressure of at least several gigapascals (GPa) is applied. If it occurs, graphitization undesirably reduces the usable mass of diamond and so limits the size of gem that can be produced, among other problems. There is also a risk of graphitizing or otherwise damaging the diamond, possibly beyond use, in case high-pressure/high-temperature (HPHT) treatment is applied that is unsuitable or not sufficiently well controlled.

A property known among CVD gems is photochromicity; that is, the instability of colour with respect to illumination, especially by sunlight or other light sources that emit substantial radiation at ultraviolet (UV) wavelengths. This temporary change in optical absorption is ordinarily caused by a reversible charge transfer processes involving specific defects uncommon in natural or HPHT synthetic diamonds, particularly the silicon-vacancy (SiV) centre. Photochromicity in CVD diamond gems is typically unhelpful in those cases where a definite colour categorization and/or letter grade is intended, and gems free of this undesirable feature may be preferred.

Yet another aspect of the quality of a diamond gem is clarity; that is, the absence of flaws visible to the naked eye. Although various types of inclusions and cracks are the most typical features leading to poor clarity, CVD synthetic diamond gems seen in the market sometimes exhibit what is termed “graining” by gemologists; that is to say, variations in local refractive index. Graining is discussed in detail, albeit primarily in reference to natural diamonds, in the article “The Impact of Internal Whitish and Reflective Graining on the Clarity Grading of D-to-Z Color Diamonds at the GIA Laboratory”, published starting on page 206 of Gems & Gemology volume 42, issue 4 (winter 2006). It is stated that this clarity characteristic is uncommonly found in natural diamonds and not always noted in grading reports. Graining interferes with the intended light propagation path in a polished gem, which may lead to a perceived loss of transparency and contrast.

Having in mind the above requirements on thickness and quality, none of which are simple to achieve in isolation, let alone in combination, it is also desirable to produce CVD synthetic single crystal diamond material as economically as possible, whether this is for gem or industrial applications. Technical requirements for low-cost, scalable CVD single crystal diamond production can be understood generically as measures which maximize the quantity of polished carats produced per unit of input resource (such as human labour, consumables, energy and so on). The inputs are closely linked; for example, a key to minimization of the labour requirement is automation, which depends on a reproducible, large-batch production process. Large production batches in turn require many, or large, reactors, although to minimize capital expenditures on duplicate equipment the latter may be preferable as far as it is technically feasible. The most important basic factors can hence be seen to be the number of single crystal diamonds able to be grown simultaneously in one reactor, and the growth rate achievable when doing so.

Faster growth of fewer crystals at once can produce diamond at an equivalent volumetric rate to slower growth of more of them, although growth rates sufficient to justify making only one single-crystal sample at a time per reactor may be difficult to achieve while maintaining both material quality and the overall level of process inputs per yielded carat. For instance, it may be harder to grow one crystal at 1 mm/h using 0.5 KW of electricity than to produce 100 such crystals in a single growth reactor in one synthesis run, each at a vertical growth rate of 0.01 mm/h and using a total of 50 KW of electrical power. The latter option may also save much of the time and effort that would have been involved in starting and stopping the one-sample process, for example, 100 or more times in the course of making 100 crystals, if 100 are needed. Although the values given in this example are purely hypothetical and in reality will depend on the particular reactor and process, those skilled in the art will recognise the basic logic. It may be commercially advantageous, therefore, to synthesize a plurality of single crystal CVD diamonds together within a reactor.

Non-uniformities can exist among such a plurality of crystals in terms of their morphology (including the presence of cracks), growth rate, or impurity content and distribution. As described in WO2013/087697, even if the gas phase chemistry and plasma environment are controlled to be substantially uniform, non-uniform uptake of impurities can still occur due to temperature variations at the growth surface which affect the rate of impurity uptake. Additionally, the growth rates of different crystal facets have distinct temperature dependences, so unintended variations in temperature can also lead to difficulties controlling crystal morphology, where such control is desirable to avoid cracking among other problems. Temperature variations can be in a lateral direction relative to the growth direction at a particular point within the deposition area (i.e., spatially distributed), and/or parallel to the growth direction due to variations in temperature over the duration (through the thickness) of a growth run (temporally or height-distributed). The proportion of grown diamond material that is suitable for a given application will typically vary depending on the filling fraction of the reactor, and a practitioner who tries to synthesize as many crystals will physically fit is unlikely to achieve good results by doing so. An optimum balance may therefore exist between the volume of diamond grown per unit of input resource and the sensitivity of the process, product, and/or application to any non-uniformities that may occur while attempting to increase this value.

The gem application offers an important counterpoint to the idea that higher-purity diamond material is better by default whenever no particular defects are required, as material containing substantial concentrations of impurities may still have very little visible colour (as discussed in, for example, WO2006/136929) and thus be desirable as a gem, while the relatively low growth rate of high-purity CVD diamond material makes it time-consuming and expensive to fabricate a thick layer. This and other commodity applications requiring relatively large pieces of CVD diamond may therefore motivate particular optimization of the synthesis process for growth rate and morphology, even potentially at the expense of purity.

One way to control growth rate and morphology is through deliberate addition of defects in the form of dopants. Nitrogen is one of the most important dopants in CVD diamond synthesis, as it has been found that providing nitrogen in the CVD process gas increases the growth rate of the material and can also affect the formation of structural crystallographic defects such as dislocations, potentially making the diamond less friable (and therefore easier to grow as a thick layer without cracking) than it if had not contained nitrogen. As such, nitrogen-doped single crystal CVD synthetic diamond material has been extensively investigated and reported in the literature. The outcome of nitrogen doping can vary significantly depending on the amount of nitrogen incorporated into the diamond. As discussed in WO2004/046427, low-level nitrogen doping can be beneficial to reduce strain within the CVD crystal, without having much effect on optical absorption, or indeed growth rate. On the other hand, larger nitrogen additions facilitate growing such material as disclosed in WO2003/052177, for which the growth rate is such as to form a thick layer relatively quickly, which however may be noticeably brown in colour. In the extreme, excessive nitrogen concentration in the CVD process gas can lead to rapid, uncontrolled growth of either poor-quality diamond (having, for example, inappropriate morphology or cracks) or material that contains a significant non-diamond (for example, graphitic) fraction, with correspondingly limited value of the product for any application requiring diamond.

Returning to WO2004/022821, it is taught that not only the hue can be changed by heat treatment, but also the overall level of optical absorption reduced, such that it is possible to consider growing CVD single crystal diamond that in its initial state will be unacceptably absorbing for a given application, but which will become suitable after treatment. Such a strategy can be advantageous when the treatment process is relatively economical compared to longer growth, in which case a practitioner might employ nitrogen doping (or other methods) to reduce the synthesis time for the diamond material rather than be bound by the optical absorption requirement of the final product. Such optimization can be seen as distinct from post-growth heat treatment as it might be applied to improve the acceptability of diamond produced according to a poorly controlled synthesis process, since it will typically require a high degree of predictability of synthesis and treatment outcomes if there is to be any confidence in meeting both a product specification and a cost target.

Little prior art exists that speaks both of growing a plurality of CVD single-crystal diamonds and the distribution (consistency or otherwise) of properties resulting among said diamonds. Less still is known on conditions necessary to grow such a plurality of single-crystal diamonds with desirable properties for specific applications at high yield. Considerations relating to uniformity over an area are known in the context of polycrystalline diamond wafers or thin films, but the requirements for growing multiple, relatively large, substantially separate single crystal diamonds bear no relation to what has been disclosed in this respect.

### SUMMARY OF THE INVENTION

It is desirable to provide a method that provides consistent, large-scale production of high-quality single crystal CVD synthetic diamond layers of a certain minimum thickness. Much is already known both on single-crystal diamond synthesis, and on heat-treating the resulting single crystal diamond material to achieve certain properties desirable for specific applications. However, there has not previously been disclosed a single crystal CVD diamond having the combination of advantageous properties achieved in embodiments of the present invention. Furthermore, there has not previously been disclosed any process suitable for economical large-scale production of CVD diamond having reproducible properties such as size and colour grade in a single run.

According to a first aspect, there is provided a CVD single crystal diamond having the following characteristics:
a smallest linear dimension (for instance, length, width, or depth) no less than 3.5 mm;
a concentration of single substitutional nitrogen atoms in their neutral charge state (Nₛ⁰) as measured by EPR of between 20 and 250 ppb; and
a hue angle, h_{ab}, between 75 and 135°.

WO2011/076643 discloses a CVD single crystal diamond with h_{ab} greater than about 80° that is at least partly attributable to Nₛ⁰ absorption. However, such a sample is constrained to have Nₛ⁰ concentration greater than about 0.5 ppm (500 ppb), which is twice the maximum value of the present invention and inconsistent with a colour grade of J or less in a gem of about 1 carat or greater. WO2011/076643 moreover teaches away from HPHT annealing as a means to achieve such a hue angle, as it is described as an expensive process that can be subject to poor yield due to cracking, and instead chooses to add oxygen to the synthesis process gases to reduce the brownness of the material in an as-grown state.

In further comparison, HPHT annealed CVD single crystal diamonds having h_{ab} about 100° and about 115° are disclosed in examples 4 and 5 of WO2004/022821. These diamonds had minimum linear dimension of 2 and 3 mm respectively, corresponding in both cases to the growth thickness. Although they were described as near-colourless at their actual sizes, they contained 1.1 and 2.2 ppm Nₛ⁰, so if similar material had been available at sufficient sizes for a gem of about 1 ct or greater, said gem could not have been near-colourless. In contrast, the material according to some embodiments of the present invention can readily be grown to a thickness of at least 3.5 mm, and in fact at least 6 mm as shown by example; and the resulting 1 to 2 ct gems are at least near-colourless in grade after annealing. While Nₛ⁰ concentrations down to 50 ppb are claimed in WO2004/022821, the hue angle corresponding to such values is specified as being less than 65°.

The CVD single crystal diamond optionally has a total concentration of nitrogen vacancy centres in their neutral and negative charge states (NV⁰ and NV⁻), that is less than 0.1 times the Nₛ⁰ concentration or less than 10 ppb, whichever is greater. The CVD single crystal diamond optionally has a hue angle, h_{ab}, selected from any of between 85 and 125°, between 9° and 120° and between 95 and 115°. Both of these features will result from a more closely optimized heat treatment process, and will provide a better approximation to the desirable “cape” yellow hue.

The CVD single crystal diamond optionally displays SiV luminescence, quantitated by the ratio of the total peak area of the SiV zero-phonon lines to the peak area of the first-order diamond Raman signal in a photoluminescence measurement performed at a temperature of 77 K using an excitation wavelength of 660 nm, selected from any of less than 0.5; less than 0.1; less than 0.05; and less than 0.01. Such values indicate diamond material with very low silicon impurity, which as a result will not be observably photochromic.

The CVD single crystal diamond optionally has at a temperature of 20° C. a low optical birefringence, indicative of low strain, such that when measured over an area of at least 3 mm×3 mm the third-quartile value of the difference between the refractive index for light polarised parallel to the slow and the fast axes, averaged over the sample thickness, does not exceed a value selected from any of 1×10⁻⁴, and 5×10⁻⁵. These low birefringence values are indicative of a sample suitable to make single crystal CVD diamond that is free of “graining”, which could otherwise affect its perceived clarity.

The CVD single crystal diamond optionally has a total volume selected from any of at least 60 mm³, at least 80 mm³ and at least 100 mm³. These volumes will apply if for example it is finished as a round brilliant gem weighing from about 1 ct to greater than about 1.75 ct.

The CVD single crystal diamond may optionally be in the form of a gem, having a chroma, C*_{ab}, selected from any of less than 8, less than 6, and less than 4. Such values may be measured, for example, for a gem that is at least near-colourless.

The CVD single crystal diamond may optionally be in the form of a gem, having a colour grade following the Gemological Institute of America (GIA) scale and methodology, that is selected from any of D, E and F when the Nₛ⁰ concentration is between 20 and 100 ppb, and selected from any of G, H, I, and J when the Nₛ⁰ concentration is between 80 and 250 ppb. Such ranges and values have not been known in combination prior to the present invention, and in some embodiments these can separately be chosen in order, for instance, to serve different market segments.

The CVD single crystal diamond may optionally be in the form of a polished sample, which may include a gem, having a clarity grade, following the Gemological Institute of America (GIA) scale and methodology, that is selected from any of VS₂, VS₁, VVS₂, VVS₁, IF, and FL. These clarity grades correspond to samples that either have no clarity defects, or have such defects which however are only observable under magnification and not with the naked eye. Some embodiments of the invention provide single crystal diamond that will typically qualify for one of these grades, allowing gems formed from it to be sold without limitation as either commercial or premium quality goods.

The CVD single crystal diamond optionally comprises H3 (NVN⁰) centres. H3 centres are typically formed within the disclosed material when it is heat-treated at a sufficient temperature and for a sufficient time to achieve the desirable yellow hue. If detectable, photoluminescence from the H3 centres can be compared with that from other defects as an aid to establishing annealing conditions that are within an optimum range.

The CVD single crystal diamond optionally displays a (NV⁰+NV⁻)/H3 ratio of less than 30 in a photoluminescence measurement performed at a temperature of 77 K using an excitation wavelength between 455 and 459 nm, where each of the NV⁰, NV⁻, and H3 defects is quantitated by the peak area ratio of its zero-phonon line to the first-order diamond Raman signal. The value of the ratio is optionally selected from any of less than 20, less than 15, less than 10, less than 5, and less than 2. Such an observation indicates annealing conditions sufficient to accomplish the hue transformation from as-grown to yellow as fully and completely as possible in a given sample.

The CVD single crystal diamond optionally displays a N3/H3 ratio of less than 0.1 in a photoluminescence measurement performed at a temperature of 77 K using excitation wavelengths of between 323 and 327 nm for N3 and between 455 and 459 nm for H3, where each of the defects is quantitated by the peak area ratio of its zero-phonon line to the first-order diamond Raman signal. The value of the ratio is optionally selected from any of less than 0.05, less than 0.02, and less than 0.01. Values at this level are consistent with a heat treatment process not unduly harsher than necessary to achieve hue angles in the desirable range within the scope of the present invention.

Thus, the desirable qualities of the disclosed material constitute at least many, and in some embodiments substantially all of those necessary to make broadly appealing, high quality CVD synthetic diamond gems designated as colourless or near-colourless. Additionally, the CVD synthetic diamond material is reproducibly, economically, and scalably manufacturable with presently available technology.

The applications of the diamond are not limited to gems. As an option, the CVD single crystal diamond is formed into a mechanical element. Such an element typically has a wear surface, that is subject to a sliding or moving contact with another surface. Non-limiting examples of such a mechanical element include wire drawing dies, graphical tools, stichels, and high pressure fluid jet nozzles, such as high pressure water jet nozzle.

As an alternative option, the CVD single crystal diamond is formed into an optical element. Exemplary optical elements include intracavity optical elements, high power transmission optical elements, Raman laser optical elements, etalons, and an Attenuated Total Reflection (ATR) optical elements.

According to a second aspect, there is also provided a method for making the CVD single crystal diamonds described above in the first aspect. The method comprises:
locating a plurality of single crystal diamond substrates on a substrate carrier within a chemical vapour deposition reactor;
feeding process gases into the reactor, the process gases including a hydrogen-containing gas, a carbon-containing gas, and a nitrogen-containing gas, where the relative quantities of these gases are such as to be stoichiometrically equivalent to a C₂H₂/H₂ ratio between 1% and 5% and a N₂/C₂H₂ ratio between 4 ppm and 60 ppm;
growing the plurality of single crystal CVD diamonds on the surfaces of at least some of the plurality of single crystal diamond substrates at a temperature of between 750° C. and 1100° C.; and
annealing at least some of the resultant plurality of single crystal CVD diamonds at a temperature of between 1700° C. and 2200° C.

The present method optionally entails that the growth on the substrates is performed without interruption as a single CVD synthesis cycle or “run”. Such an uninterrupted process is advantageous over a “stop-start” or layer-by-layer process in, for example, improving equipment utilization efficiency, avoiding the need to prepare the crystals for growth multiple times, and preventing any deleterious effects of interfaces formed between layers grown in successive growth cycles in the material produced. In our preferred embodiment, as detailed by example, growth to full thickness is substantially always performed without interruption.

The present method optionally entails that the CVD synthesis provides a volumetric growth rate for single-crystal diamond material that is selected from any of at least 10 mm³/h, at least 20 mm³/h, at least 30 mm³/h, at least 40 mm³/h, and at least 50 mm³/h.

The present method optionally entails that the annealing is performed under diamond-stabilising pressure. This allows higher temperatures and/or longer annealing times to be used without any loss or damage to the CVD single crystal material by graphitization.

The present method optionally entails that the total volume of single-crystal diamond treated in a single annealing operation is selected from any of at least 500 mm³, at least 1000 mm³, at least 1500 mm³, and at least 2000 mm³.

The present method optionally entails that the carbon-containing and hydrogen-containing process gases are provided in quantities stoichiometrically equivalent to a C₂H₂/H₂ ratio in a range selected from any of 2% to 4%; and 2.5% to 3.5%. These ranges are such as to provide a balance between growth rate and material quality.

The present method optionally entails that the nitrogen-containing and carbon-containing process gases are provided in quantities stoichiometrically equivalent to a N₂/C₂H₂ ratio in a range selected from any of 5 ppm to 20 ppm; 10 ppm to 50 ppm; 7 ppm to 15 ppm; and 15 ppm to 35 ppm. These ranges have been found suitable to provide CVD single crystal diamond material suitable for colourless to near-colourless synthetic gems after HPHT annealing. More particularly, in certain embodiments, a choice among these ranges enables the selective production of either colourless or near-colourless gems.

The present method optionally entails that the plurality of CVD single crystal diamonds are grown at a temperature selected from any of between 800° C. and 1050° C.; between 800° C. and 950° C.; and between 825° C. and 925° C. To maintain all growing samples within these narrower ranges offers the possibility, in certain embodiments, of achieving more closely uniform nitrogen doping and a tighter distribution of colour grades among diamonds finished as gems.

The present method optionally entails that the annealing is performed at a temperature selected from any of between 1750° C. and 2100° C.; between 1800° C. and 2000° C.; and between 185° and 1950° C. These narrower temperature ranges are such as to provide a balance between the effectiveness and rapidity of the annealing process, and the difficulty of accomplishing it with common equipment, materials, and processes.

The present method optionally entails cutting and polishing at least one of the plurality of single crystal diamonds to form a gem. It further optionally provides that the said gem comprises at least a portion of the single crystal diamond substrate.

### BRIEF DESCRIPTION OF THE DRAWINGS

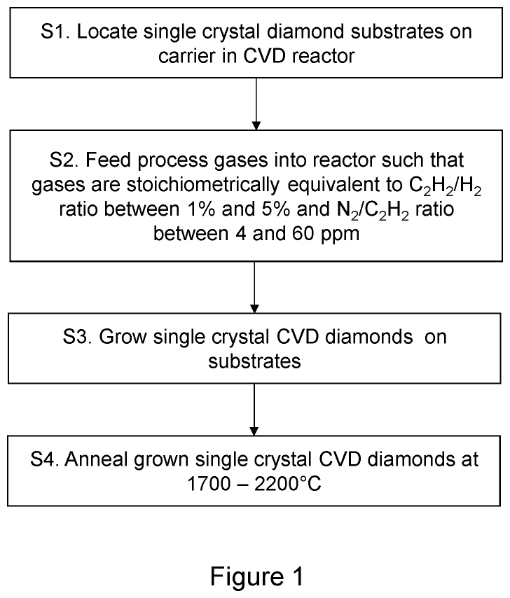

The invention will now be more particularly described, by way of example only, with reference to the accompanying drawing, in which FIG. 1 is a flow diagram showing exemplary steps for making CVD single crystal diamonds.

### DETAILED DESCRIPTION

CVD single crystal diamonds such as gems are widely available in the market, but a cursory study of the goods presently available shows that there is a wide and continuous range of qualities and sizes. The inconsistent combinations of clarity, colour, and size, sometimes with no two available samples the same even from the same manufacturer, suggests that methods are not yet known which enable reproducible, scalable production of good quality, relatively large single crystal CVD diamond pieces.

The present inventors have developed a high-quality, consistently volume-manufacturable CVD synthetic diamond. Here, “volume-manufacturable” means that not only are many tens of pieces of single crystal diamond material able to be produced at one time within a single reactor, but also that yield expectations are such that a production run consisting of multiple synthesis cycles may be planned and set up on as many CVD reactors as needed to meet a larger volume requirement, with predictable cost of manufacture and defined production timescale. Some embodiments of the invention allow the skilled person to choose, at the time of synthesis and in a manner which does not greatly affect production costs, the GIA colour category or grade that will apply to the finished product when cut and polished as gems.

The conditions described herein provide a CVD single crystal diamond material with relatively low internal strain, thus minimizing yield loss due to cracking and avoiding significant stress-induced birefringence and/or visible graining in the finished goods. Essentially no yield-limiting cracks occur in synthesis runs according to some embodiments. This is due in part to using single-crystal substrates (seeds) with very few structural defects, for example non-diamond inclusions, twins, polishing damage, or surface-intersecting dislocations. A suitable way to achieve the required high structural quality is to use vertically cut CVD substrates, as described in WO2004/027123, the contents of which are incorporated herein by reference. In that disclosure, a method of producing a plate of single crystal diamond is described, which includes the steps of providing a diamond substrate having a surface substantially free of structural defects, growing diamond homoepitaxially on the surface by CVD, and severing the resulting enlarged crystal transverse, typically normal (that is, at or close to 90°), to the surface of the substrate on which diamond growth took place, to produce a plate of single crystal CVD diamond. This plate, or more typically multiple such plates taken from each crystal, is used as a substrate for further growth. As the extended defects (dislocations and bundles thereof) tend to follow the growth direction, slicing the diamond transverse to the growth direction ensures that they are much less likely to intersect the new largest face, which as a result has a low propensity to nucleate or propagate dislocations.

It is advantageous to use synthesis conditions for growing the substrate that are sufficiently similar to those used for the final diamond product, such that the colour of the substrate differs minimally from that of the rest of the crystal. In so doing, the need to remove the substrate before, for example, finishing as a gem is avoided, with the total usable thickness then being the sum of the substrate thickness and the thickness of the subsequent growth.

It has been found that CVD single crystal diamond according to certain embodiments of the invention, when finished in the round brilliant gem shape with a GIA Very Good or Excellent cut grade and weighing between 1 and 2 ct, must contain 100 to 250 ppb of neutrally charged single substitutional nitrogen (Nₛ⁰) if such gems are to fall into the near-colourless category (GIA grades G, H, I, or J), or 20 to 80 ppb Nₛ⁰ if they are to be considered colourless (grades of D, E, or F). In all cases these concentrations are as measured by electron paramagnetic resonance (EPR) spectroscopy, preferably after deep-UV illumination to be certain of avoiding any charge transfer effects. Colour grades form a continuous scale and so intermediate concentrations of 80 to 100 ppb Nₛ⁰ will place the gems close to the border between the colourless and near-colourless categories, which however could result in an uncertain categorization given colour grades assigned using the GIA methodology can commonly vary by one unit among different gemological laboratories. Nₛ⁰ concentrations of below 20 ppb for colourless CVD single crystal diamond gems will not provide any further improvement in colour grade (a diamond gem graded D need not be completely free of colour), but will make synthesis more difficult and time-consuming due to the combination of lower growth rates and a propensity toward increased strain known from WO2004/046427.

Given the aforementioned Nₛ⁰ to grade correspondence, which has not been previously disclosed, another issue to be addressed by the present invention is how can a given Nₛ⁰ concentration, and therefore a particular colour category or grade, be achieved in practice? The solution herein is to recognise that the ratio of nitrogen to carbon made available in the CVD process gas is reflected in that of the solid diamond, and so to choose this ratio appropriately to the desired intensity of yellow colour in the product as further elaborated in the example below. The available carbon fraction relative to hydrogen is then chosen in order to achieve a target growth rate. A person skilled in the art will appreciate that such choices are reactor- and process-dependent, and therefore the examples herein are indicative. This is in part because principal factors influencing diamond growth rate and material properties are the fluxes of C₁ radical species (for example, C atoms, CH, CH₂, and CH₃), nitrogen radical species (for example, N atoms, NH, and CN), and H atoms that are incident on the growing diamond surface, which however are difficult to measure and usually unknown to the practitioner, being only indirectly determined by the process and reactor design. There are also other viable chemistries apart from the hydrogen/methane/nitrogen mixtures that are usually considered to be the most practical and economical basis for an industrial process: for example, one can envisage using acetylene or propane in place of methane, and ammonia or nitrous oxide in place of molecular nitrogen, among many other possibilities. Reactions among the feedstock materials may also need to be considered. For example, it is known to add some amount of molecular oxygen to a hydrogen/methane process mixture, and if done this requires carbon atoms from the methane to be discounted by the number of oxygen atoms added due to the formation, in aggregate, of CO, which is not effectively decomposed into C₁ radicals in the chemical environment of a plasma CVD process and therefore does not contribute toward diamond growth. A simple and useful calculation that covers a broad range of process chemistries, including those based on carbon dioxide and methane with little or no molecular hydrogen, is to assume that the feedstocks mutually react to become a mixture consisting of stoichiometric amounts of molecular nitrogen (N₂), acetylene (C₂H₂), molecular hydrogen (H₂), and carbon monoxide (CO), and optionally a balance of gases not containing N, C, H, or O atoms, such as noble gases. Though not commonly used, processes containing halogens can be accommodated as well by treating any halogen as hydrogen. Therefore, although methane is used rather than acetylene as the carbon source in the examples below, the synthesis environment is also specified also in terms of the equivalent (calculated) N₂/C₂H₂ and C₂H₂/H₂ ratios to better facilitate comparisons with other process chemistries.

Having synthesized the diamond crystals, heat treatment is undertaken to effect a hue transformation from the original brownish colour to the desirable yellow. In a preferred embodiment, the heat treatment is performed at temperatures greater than 1600° C. and at diamond-stabilizing pressure as described in WO2004/022821, the contents of which are incorporated herein by reference. This is known as high-pressure, high-temperature (HPHT) annealing. To achieve such pressures, HPHT requires exerting considerable mechanical force upon the material to be treated, which can cause microscopic cracks (if present) to enlarge to an extent undesirable for the final application. Such cracks are typically associated with polycrystalline material that occurs as a by-product on the surface of the CVD single crystals. As preferably no portion of this “skin” is included in a finished CVD single crystal diamond gem in order not to compromise clarity, the CVD single crystal diamonds are advantageously prepared for HPHT annealing by removing any polycrystalline material potentially harbouring cracks, thereby avoiding wastage through further cracking. Still more advantageously, the crystals may be part-finished or fully finished as gems prior to annealing, which due to the fact that the finished product is necessarily smaller than the as-grown crystals due to the removal of some portion by cutting and/or polishing, can enable a greater number of gems to be processed in each HPHT annealing operation.

As with CVD synthesis, persons skilled in the art will appreciate that the process parameters required for HPHT annealing depend in specifics on the apparatus, materials, and methods employed, which can vary among practitioners for incidental reasons such as relative cost without affecting the ability to attain given conditions. Therefore, again, specific examples are provided for guidance rather than as limiting cases. The general approach, as described herein, consists in the irreversible conversion of those optically active point defects that are formed within a diamond during CVD synthesis at a comparatively low temperature, into more thermodynamically stable forms by reacting them together at a relatively high temperature.

The principal optically active point defects incorporated during CVD synthesis, which is typically carried out at temperatures between 70° and 1200° C., are Nₛ⁰ and vacancy complexes (e.g., clusters and chains, which contribute to the brown colour). By HPHT annealing at temperatures greater than around 1600° C., the vacancy complexes can be made to dissociate. Because of this, it is not necessary for all applications to minimize brownness in the as-grown state, as it can be removed later. The resulting free vacancies migrate within the crystal until they encounter another defect and adopt a form that is stable at the higher temperature. Commonly, they associate with substitutional nitrogen atoms to form NV defects, which convey a pinkish colour that may range from orangey pink, through reddish pink, to purplish pink.

Free vacancies may also associate with substitutional silicon atoms, if present, to form silicon-vacancy (SiV) defects. Silicon is prevalent as an impurity in CVD synthetic diamond material and commonly originates from CVD reactor components such as fused silica dielectric barriers, although deliberate silicon doping using silicon-containing gases is also known. Silicon is predominantly incorporated into CVD diamond as substitutional atoms, Sis, which are not optically active and are therefore difficult to detect in the material at low concentrations. The SiV defect, on the other hand, is formed in preference to NV on annealing and is readily observable in both its neutral and negative charge states. At room temperature, SiV⁰ exhibits an absorption line at 946 nm (1.31 eV) and associated phonon side bands, while SiV⁻ exhibits an absorption line at 737 nm (1.68 eV) and similarly associated bands. The side bands of SiV⁰, in particular, extend far into the visible spectrum and can cause samples containing this defect in sufficient concentration to appear grey or greyish-blue. Notably, SiV is a strong electron acceptor, so that if it is present alongside Nₛ in a diamond sample, charge transfer between them will typically cause the dominant charge states to be Nₛ⁺ and SiV⁻, neither of which contributes significantly to the perceived colour of the sample. CVD single crystal diamond containing a relatively high concentration of substitutional nitrogen but made substantially free of optical absorption due to Nₛ⁰ by silicon doping is disclosed in WO2006/136929. A significant disadvantage of that approach is that the resulting CVD single crystal diamond will be strongly photochromic. As described in “Optical properties of the neutral silicon split-vacancy center in diamond”, published as article number 245208 in Physical Review B volume 84 (December 2011), UV illumination of such samples causes the ionization process Nₛ⁺+SiV⁻→Nₛ⁰+SiV⁰, which imparts a greyish colour from the combination of yellow Nₛ⁰ and grey-blue SiV⁰ optical absorptions. This photochromism in itself, as well as the resulting colour, are both highly undesirable for the colourless and near-colourless gem application and in certain industrial applications, and avoiding it requires a practitioner to limit the concentration of SiV defects to no more than some tens of parts per billion, and preferably less. For annealed samples, fulfilling this requirement will typically involve minimizing the total concentration of silicon in the CVD single crystal diamond material, as otherwise the formation of SiV in the presence of free vacancies is essentially unavoidable.

At treatment temperatures around 1700° C., NV defects are able to migrate as a unit within the crystal, such that they may encounter either other defects or one another, and again, associate to form a new defect that is stable at such temperatures. Such a defect is the H₃ centre, which consists of two substitutional nitrogen atoms separated by a vacancy in an overall neutral charge state, (N—V—N)⁰. H3 exhibits an optical absorption line at 503.2 nm (2.463 eV) and associated bands, which confers a yellow colour. It should be noted that the association of two NV defects, which is an important route to forming H3 centres, will release a free vacancy, i.e. NV+NV→NVN (H3)+V. This vacancy may go on to associate with Nₛ to re-form NV⁻, and therefore there is no sharp temperature threshold for residual NV defects to be removed by conversion to H3. Rather, the degree of conversion (and so the extent of the colour change from pinkish to yellow) depends as well on the duration of annealing and the availability (or otherwise) of excess Nₛ to facilitate the reaction NV+Nₛ→NVN. One approach to ensuring a yellow final hue when treating material having unknown defect concentrations is simply to increase the temperature still further in order to dissociate NV. However, to do so can require very high temperatures, for example 2200° C. or more, and as such comes at the considerable risk of graphitizing and destroying the material that was supposed to have been improved through treatment. Graphitization at these high temperatures can be inhibited by applying greater pressure, for example 8 GPa or more, which however requires either larger and more powerful pressure generation apparatus, or a reduction of the volume that is able to be subjected to high pressure. Due to practical limitations, the more common solution is the latter, although this inevitably reduces the quantity of CVD single crystal diamond material that can be processed in each annealing operation, without affording a corresponding reduction in treatment time or the quantity of labour or consumables required per HPHT cycle. As such, the use of excessively high temperature and pressure will in general make the annealing step less economical, which is clearly undesirable where the reason for undertaking such annealing is in part to minimize the total cost of production for diamond material.

It has been found that when treating the disclosed CVD single crystal material, a desirable, photostable, pale yellow colour with no brown or pink nuance will result by annealing within a predictable and comparatively narrow range of temperatures comfortably below that which will convert diamond to graphite under typical pressures attainable by HPHT practitioners. By finding and subsequently reproducing process conditions that provide temperatures within this range, a skilled person will be enabled to treat the disclosed material reliably, in volume, without any graphitization or noticeable surface damage, even when it is fully finished as cut and polished parts such as gems. However, the optimum temperature to accomplish the hue transformation without graphitization is at least partly dependent on the applied pressure and the duration of annealing, and in any case it is not straightforward to accurately measure the temperature and/or pressure that has been achieved in many types of HPHT apparatus. Therefore, there is further disclosed a measurement methodology which will enable a skilled person to determine this by examination of treated material alone. Details of the actual measurements are given in the example.

The most direct quantitative indication of minimally sufficient conditions is the measured CIELAB hue angle, h_{ab}, as defined by the International Commission on Illumination in CIE 015:2004: “Technical Report, Colorimetry, 3^{rd} Edition”. Importantly for present purposes, for otherwise equivalent material this value depends almost solely on treatment conditions, and is practically independent of the size and shape of the sample (so the measurement does not require a fully finished gem, if for example a gem is the intended end product). The procedure to calculate h_{ab} from optical absorption spectra is detailed in CIE 015:2004, where such spectra may be measured, for example, in transmission for a polished, parallel-sided sample, or using an integrating sphere for irregular shapes including gems. Other measurement approaches are also possible, one of which is used in the example. In the CIELAB colour model, h_{ab}=0° represents red and h_{ab}=90° is yellow. Intermediate values, signifying brown-orange hues, are typical of untreated or too lightly treated CVD material. With increasing treatment temperature, hue angle will at first remain unchanged while no reaction occurs, and then tend to decrease toward a minimum due to the formation of NV defects as conditions approach the optimum range. The lower limit of the optimum regime, whereupon h_{ab} will begin to increase again, lies at only slightly higher temperature (about 50° C. greater) than the hue angle minimum. Treatment at the lowest optimal temperature (hereafter, the threshold temperature, about 1700° C.) will, however, require a long time to accomplish the desired hue transformation, as the hue angle will increase toward yellow only slowly. If graphitization occurs at or below the threshold temperature, pressure must be increased to widen the process window. The hue angle change becomes more rapid with increasing temperature as NV defects become more mobile, and at about 1750° C., the required treatment time decreases to typically less than an hour. Further increases in temperature to shorten the required annealing time are at the practitioner's discretion and may depend on the economics imposed by their choice of apparatus, materials, and processes. Complete hue transformation gives 90<h_{ab}<120°, i.e. yellow to slightly greenish-yellow hues. The precise hue angle at the endpoint depends on the balance between the concentrations of Nₛ⁰ and H₃ in the annealed material, which is largely a function of its brownness in the as-grown state: browner material contains more vacancies and so its treatment will produce more H3.

A good indicator of conditions that lie beyond the point of diminishing returns when treating the CVD single crystal diamond material, and hence unnecessarily close to the graphitization threshold, is the formation of the N3 defect in significant concentrations. The N₃ centre consists of three substitutional nitrogen atoms surrounding a vacancy (3N+V) and displays an absorption line at 415.2 nm (2.985 eV) plus associated vibronic bands. Because of this absorption at the blue end of the visible spectrum, it also confers a yellow hue, although in CVD material it typically will not attain concentrations such as to noticeably affect the observed colour. Importantly, N3 is more thermodynamically stable than H3 and so forms in preference at high temperatures, especially at or above 2200° C. By sensitively detecting N3 (for example, by photoluminescence spectroscopy) and maintaining its concentration in the disclosed material below a certain level relative to other relevant defects, for example H3, a practitioner can locate the upper limit of the optimum regime without requiring direct knowledge of temperature and pressure.

### EXAMPLE

A plurality of CVD single crystal diamond substrates was fabricated as transversely cut plates, as described in WO2004/027123. The plates had (100)-oriented faces and edges, and were finished with dimensions of 4.5×4.5×0.3 mm where required to make a 1 ct round brilliant gem product, or 5.5×5.5×0.3 mm for a similar 2 ct product. The substrates were attached to a suitably prepared substrate carrier following WO2005/010245 and WO2017/050620, and placed in a CVD reactor.

The design and construction of the CVD reactor was such as to minimize sources of silicon impurity in the diamond material. For example, the fused silica dielectric barrier, which constituted a minor portion of the process-exposed surface area of the reactor as described in WO2012/084660, was well-cooled and situated far from the deposition area. Such a reactor can offer process purity sufficient to produce the electronic-grade single crystal CVD diamond disclosed in WO01/096633 and WO01/096634.

Process gases were fed into the CVD reactor that included molecular hydrogen, a carbon-containing gas (in this example, methane) and a nitrogen-containing gas (here, molecular nitrogen). CVD reactors used by different practitioners vary widely in their performance characteristics, and the synthesis processes employed can also differ in incidental but nonetheless significant ways, for example by growth temperature. Accommodations for these differences are known in the art. It was ascertained that, using the present apparatus, material containing 100 to 250 ppb Nₛ⁰, as required for near-colourless CVD single crystal diamond gems, would result from a synthesis process employing gas-phase concentrations equivalent to 18 to 34 ppm N₂/C₂H₂ by the calculation methodology described above, which was provided by 9 to 17 ppm N₂/CH₄ in our process chemistry. Similar gems containing 20 to 80 ppb Nₛ⁰, and therefore having colourless grades, would require 7 to 15 ppm N₂/C₂H₂ equivalent, or between 3.5 and 7.5 ppm N₂/CH₄ in our case. Importantly, the Nₛ⁰ concentration in the final product was close to linearly proportional to the equivalent N₂/C₂H₂ ratio during synthesis, which meant that only a small number of experiments were necessary to establish the needed relationship. This near-linearity, along with the high consistency of the synthesized material and treatment outcomes, encouraged the choice of the intended products by specific colour grade, rather than only by category, and so for the present examples we selected equivalent N₂/C₂H₂ ratios of 28 and 12 ppm such that the gems would have colour grades close to the middle grade within their category, i.e. H/I and E respectively. The equivalent C₂H₂/H₂ ratio was then chosen so that the growth rate was in an optimum range having regard to material quality, uniformity, and process inputs such as the total volume of gas and the total quantity of electrical power required during the course of synthesis. The optimum growth rate range was achieved using 2.5 to 3.5% C₂H₂/H₂ equivalent (CH₄/H₂ ratio between 5.5 and 7.5%). The relationship between the equivalent C₂H₂/H₂ ratio and the growth rate is known to vary depending on the reactor design, but can readily be determined by a practitioner. In our reactor, we found that it was close to linear.

Microwave energy was supplied at a frequency of either 896 or 915 MHz and a plasma of the process gases was formed within the reactor. The required operating frequency largely depends on the dimensions of the reactor and practitioners may choose to employ, for example, a microwave frequency of 2450 MHz in combination with a smaller reactor than that of the present example, without substantial departure from any other detail given herein. Single crystal CVD diamond material was grown without interruption on a surface of each of the plurality of single crystal diamond substrates to a thickness of between about 4 mm and about 6 mm. The temperature of the crystals during growth affects the amount of nitrogen incorporated for a given equivalent N₂/C₂H₂ ratio provided in the process gases. Here, temperature was measured on an area of polycrystalline diamond in between adjacent single crystals using an optical pyrometer operating at a wavelength of 2.2 μm, which was pointed through an 8 mm thick IR-grade fused silica observation window. A one-colour measurement was made assuming no transmission losses and an emissivity of 0.9 for the polycrystalline diamond, which gives a consistent and reproducible reading that is within about 10° C. of the true thermodynamic temperature, as would be measured (for example) using a two-color pyrometer. Temperatures measured in this way were in the range 825 to 925° C. for the duration of growth.

In this example, CVD single crystal diamond material usable toward the final product was grown at volumetric rates between about 45 and about 60 mm³/h per reactor, depending on the exact process parameters employed. These values correspond to between about 0.8 and about 1.1 ct of good-quality single crystal diamond being grown per reactor hour.

After growth, the CVD single crystal diamond crystals were removed from the substrate carrier, separated from any polycrystalline diamond that had grown around them, and characterized for the intensity of their brown colour. Colour measurements were made by photographing the as-grown samples in transmission (through thickness, i.e. substrate to top face) against a uniform white backlight in an otherwise dark environment. Calibrated CIELAB colour coordinates were derived with reference to a standard ANSI IT8.7/1-1993 transmissive test target photographed under the same conditions. Chroma C*_{ab} (again, according to CIE 015:2004) and hue angle h_{ab} were thus measured for each crystal, relative to a white point derived from the surrounding backlight area. The CVD single crystal diamond crystals intended for colourless gems displayed h_{ab} between approximately 55° and 65°, while those grown for near-colourless gems and having the higher nitrogen content had on average slightly larger hue angles, between about 60° and 70°. Chroma values are related to the perceived intensity of colour, with C*_{ab}=0 corresponding to neutral or no colour, i.e. white, grey, or black, and increasing values correlated to increasing saturation of any non-neutral hue. When measured at a total thickness (i.e., including the substrate) of 5.5 to 6.5 mm, CVD single crystal diamond crystals for colourless gems mostly had C*_{ab} in the range 3.5 to 5.5, whereas those for near-colourless gems tended to larger values and adopted a broader range of C*_{ab} between about 4 and 12.

Prior to annealing, any non-diamond and polycrystalline material was removed from the grown CVD single crystal diamond crystals, along with any surface defects that could increase the risk of failure by crack initiation or propagation during annealing, and the grown crystals were either semi- or fully finished as gems. A number of them were then assembled together into a compact consisting of the diamonds embedded within a matrix of pressure-transmitting salt, and the compact was placed into the HPHT apparatus. In this example, a total of between about 1500 mm³ and 2500 mm³ of single-crystal diamond (30 to 40 ct, approximately) could be accommodated in a compact and all individual samples treated to a mutually consistent result. Conditions used for HPHT treatment were indirectly estimated as 1900° C. at a pressure of 7 GPa (70 kbar), and the annealing time was approximately 10 min. At this pressure, equivalent results would have been possible, with suitable adjustment of the treatment time, at any temperature between 1700 and about 2100° C., but higher temperatures than this would have required increased pressure. As a matter of practicality, the temperature was chosen to be roughly in the centre of the optimum range for a pressure of 7 GPa. After annealing, the compact was dissolved in water to recover the diamonds and the salt. No cracking or graphitization of the diamond was observed, and those samples that were fully finished maintained their polish grade through treatment.

Electron paramagnetic resonance (EPR; also known as electron spin resonance, ESR) spectroscopy was used to quantify the concentrations of Nₛ and NV after treatment. This experimental technique was chosen for its high sensitivity (notably more so than other common methods such as infrared or UV/visible absorption spectroscopy), its quantitative accuracy, and its ability to be used on samples of any shape, including gems. It is important to note, however, that Nₛ⁺ and NV⁰ cannot be detected by EPR and so the concentrations of these must be minimized in favour of the (detectable and quantifiable) Nₛ⁰ and NV-if a representative measurement is to be made. As such, the required charge states were prepared prior to measuring, by deep-UV illumination for Nₛ⁰ and by heating to 550° C. in the dark for NV. Colourless CVD single crystal diamond samples were found to contain around 65 ppb Nₛ⁰ (average for three nominally identical samples) and an undetectable amount of NV⁻. Near-colourless samples contained around 190 ppb Nₛ⁰ (average for two nominally identical samples, one of which was also submitted to an external laboratory that provided a result identical to ours within the few-percent error of the respective measurements) and similarly undetectable NV⁻. Further measurements were made in an attempt to detect NV⁻ by other EPR schemes, but these were not successful in providing a detection as the concentration was too small. After validating the approach against a different sample (not of the present invention) that contained a detectable amount of NV⁻, it was determined that the detection limit was below 10 ppb NV⁻, although it is likely that the true value was below 5 ppb for the near-colourless sample, and below 2 ppb for the colourless sample. Thus, the concentration of NV remaining after annealing cannot have been greater than about one tenth that of Nₛ, and in all probability was lower still.

Photoluminescence (PL) spectra of the treated CVD single crystal diamond samples were measured to compare the contributions from NV, H₃, and N₃. Although PL is an exceptionally sensitive technique, defect luminescence intensities depend on the excitation and detection efficiency for the given defect as well as its concentration, so that intensity ratios of the respective signals are proportional to, but not equal to, the relative concentrations. The excitation efficiency for each defect depends on the overlap between its absorption spectrum and the excitation wavelength, and the detection efficiency depends on the fluorescence quantum yield. These influences are fixed by the physics of the defects, the chosen excitation and detection wavelengths, and the temperature at which the measurement is made. Our measurements were made at a temperature of 77 K using a liquid nitrogen cryostat, and the excitation wavelengths were 325 nm (helium-cadmium laser) and 457 nm (argon-ion laser).

Both the neutral and negative charge states of the NV defect, as well as H3, were able to be excited at 457 nm, and these were detected via their zero-phonon emission lines (ZPLs), which are located for NV⁰ at 575.1 nm (2.156 eV), NV⁻ at 637.5 nm (1.945 eV), and H3 at 503.2 nm (2.463 eV). Each of the measured ZPL intensities was divided by the simultaneously measured intensity of the first-order diamond Raman line R1₄₅₇, so that for instance NV⁰₄₅₇=I(575.1 nm)/I(R1₄₅₇), where I(·) signifies a peak area. This factored out the overall coupling efficiency, which is equipment-dependent and can also be affected for example by (orientation-dependent) reflection from the surface of a polished sample. We then examined the ratio (NV⁰₄₅₇+NV⁻₄₅₇)/H3₄₅₇, hereafter NV/H3, for both colourless and near-colourless samples. While NV/H₃ will be minimized under optimum annealing conditions, the minimum value is determined by the kinetics governing the stepwise production of H3 by formation of NV from Nₛ and a free vacancy, followed by migration of this NV to react with either Nₛ⁰ or another NV. In samples that contain little nitrogen or (especially) few vacancies, the latter process occurs with only low probability within the finite annealing time, leading NV/H3 to be larger than otherwise. This should not be taken to suggest that such samples have a pinkish hue after annealing, but rather that the concentrations of NV and H₃ are both very small, so that the dominant contributor to the (yellow) hue is Nₛ⁰. Both near-colourless samples and colourless sample synthesized at similar growth rates (hence containing a similar concentration of vacancies) had NV/H3 PL about 1.5 after annealing. Colourless samples that had been synthesized at a lower growth rate showed larger and more variable NV/H3 values, between 3 and 7 approximately, reflecting the more hindered formation of H3 in such samples. If D grade samples had been made instead of E, still larger values would be expected for the same reason.

N3 could not be observed with 457 nm excitation because its ZPL (415.2 nm, 2.985 eV) is at shorter wavelength than the excitation, so the excitation efficiency is very low. Therefore, the 325 nm laser was used to excite N3. As expected for annealing conditions not exceeding the maximum optimal temperature, N3 could not be detected in any of the samples treated at 1900° C.; nor could it be detected in samples treated at 2000° C. for 4 hours. These latter conditions are beyond what is necessary to accomplish the hue transformation, but are still within the optimum regime as there is little risk of graphitization when done at a moderate pressure of 7 GPa. To quantify the amount of N3 PL expected at our upper temperature bound, further samples were annealed at 2200° C. for 1 hour, which however required the pressure to be increased to 8 GPa in order to avoid damage. Direct ratios to H3 were difficult to infer since the spectrum excited at 325 nm contained several unassigned lines overlapping the H3 ZPL. Therefore, we examined N3₃₂₅/H3₄₅₇, that is, after rationing to the respective first-order Raman peak areas as described above. Such a combination of measurements using different excitations seems inconvenient, but in practice these excitation wavelengths (and the associated gas lasers) are among the most commonly used, with limited choices available for other wavelengths in this spectral range. N3₃₂₅/H3₄₅₇ was found to take values between 0.01 and 0.02 after the 2200° C. treatment. Somewhat larger values might be expected under the same conditions for samples that are extremely brown in the as-grown state, due to vacancy-assisted nitrogen aggregation.

Quantitative measurements of the colour of a finished gem are more difficult than those for an as-grown crystal because of specularity, multiple internal reflections, and dispersion within the polished article, which produce localized highlights and flashes of apparent colour that depend mostly on the illumination conditions and which need to be discounted to assess the true body colour of the gem. To make such measurements, the photographic approach described in WO2016/203210 was used, which is a faster but still reliable alternative to the use of a spectrophotometer and integrating sphere, and as such particularly useful when many polished gems are to be measured. Measured hue angles after annealing lay in the range 105°<h_{ab}<115° for the majority of the colourless gems and 95°<h_{ab}<105° for the majority of the near-colourless ones, indicating that all samples could be described as yellow, with no residual brown, pink, or orange colour.

Given none of the CVD single crystal diamond samples exhibited any measurable photochromicity, a PL measurement was performed for SiV at 77 K excited using a 660 nm diode laser. Due to the superlative sensitivity of low-temperature PL, a quantifiable SiV signal is nearly always observed in such a measurement on CVD synthetic diamond material, even for samples containing orders of magnitude less SiV than would be detectable in absorption.

As with the other PL measurements, the reported value is the area ratio of the SiV-PL feature to the first-order diamond Raman line, except that at low temperature SiV displays two ZPLs, at 736.5 and 736.8 nm respectively, so that SiV⁻₆₆₀=I(736.5 nm)/I(R1₆₆₀)+I(736.8 nm)/I(R1₆₆₀). In these samples, SiV 660 typically took values between 0.001 and 0.01, which are exceptionally small by the standards of marketed CVD synthetic gems. For comparison, gems obtained from third-party producers who state that they do not employ post-growth treatments gave SiV 660 typically between 0.5 and 1.5. There is, however, considerable variation among suppliers, and values between about 50 and 100 were measured for third-party gems that had been HPHT annealed.

Treated CVD single crystal diamond gems always had lower C*_{ab} as compared to the same measurement taken before annealing, signifying an overall reduction in the depth of colour. Colourless CVD single crystal diamond gems exhibited C*_{ab} between 1.5 and 3.5 (with most samples falling within the narrower range 1.8 to 2.8) for a round brilliant shape when measured viewed through the pavilion with the table facet facing downward, as is the accepted practice for colour grading such gems. For this shape and in this orientation, the observed colour intensity depends only weakly on the size (weight) of the gem, which leads 1 ct and 2 ct round brilliants to exhibit almost the same measured C*_{ab} if they are manufactured from CVD crystals synthesized and treated under the same conditions. Near-colourless CVD single crystal diamond gems were distinguished by generally larger C*_{ab} values between 3.5 and 6.5, again with most lying closer to the middle of the range, namely between 4.2 and 5.2. These values summarize a survey of several hundred gems synthesized and treated using multiple equipment sets, at different times, in different factories, and closely approximate the distributions arising in large-scale production before any quality control criteria are imposed on the final product.

We estimated GIA-equivalent colour grades based on the measured C*_{ab} values, calibrated using a set of natural diamond samples for which both C*_{ab} and colour grades were known. The colour grades for the reference samples were assigned following the methodology widely taught by the GIA and described in the article ‘Color grading “D-to-Z” diamonds at the GIA laboratory’, page 296 ff of Gems & Gemology, volume 44, number 4 (winter 2008). On this basis, the boundary between grades F and G, i.e. between the colourless and near-colourless categories, was assessed to lie at C*_{ab}=3.5, and approximately C*_{ab}=7 was taken as the upper end of the near-colourless range, beyond which samples are considered to be faintly coloured (grades of K and higher). More particularly, 1.8<C*_{ab}<2.8 measured for the majority of colourless samples corresponds approximately to an E grade, and the near-colourless samples falling in the range 4.2<C*_{ab}<5.2 would be graded H. An I grade would result for those with 5.2<C*_{ab}<6.2, in our estimation. Hence, even allowing for reasonable errors in the grade estimations as well as possible discrepancies between grading laboratories, all gems measured fell within the colour category intended for them at the production planning stage.

Some finished CVD single crystal diamond gems were submitted to the GIA laboratory in New York, which assigned grades that were in nearly all cases within one grade of our own. Namely, the GIA grades were typically E for the colourless gems and typically I for the near-colourless ones. Furthermore, within each of the colour categories, different samples were almost always given identical grades by the GIA, there being only one exception to this. If the GIA grades had differed systematically from the estimates, the N₂/CH₄ ratio (or equivalently, the calculated N₂/C₂H₂ ratio) could be adjusted in the synthesis process to incorporate either less or more nitrogen into the diamonds and so decrease or increase the final grade as appropriate. The CH₄ fraction (calculated C₂H₂/H₂ ratio) would then be adjusted to maintain the growth rate at the economically optimum value. The HPHT annealing step would not have needed to be modified.

Birefringence measurements were made on the CVD single crystal diamond material. Grown diamond material was formed into cubes. The cubes had {110}-oriented side faces with edge lengths equal to the substrate diagonal, so that they circumscribed the area of the original substrate, and {100}-oriented top and bottom faces. The cubes were annealed as described above, and then horizontally cut into plates 0.7 mm thick, with both major faces polished. Birefringence (defined as the difference between the refractive indices for light polarised parallel to the slow and the fast axes, averaged over the sample thickness) was measured for the plates at a wavelength of 590 nm using a commercial instrument (Thorlabs LCC7201), and for most of the area it took values on the order of 10⁻⁵, well within the scope of WO2004/046427, which describes material suitable for optical applications such as etalons. Exceptions were the regions directly above the substrate edges, where dislocations tend to be concentrated at the boundaries between the lateral and vertical growth sectors, and which showed localized maximum birefringence on the order of 10⁻⁴. Although the inclusion of these more-birefringent portions of the crystal might not be preferred in all technical applications, it was found that they are not detrimental to the visual clarity of CVD single crystal diamond given that they occupy only a small fraction of the total volume, and in any case the maximum birefringence is less than 1% that of synthetic moissanite (4.3×10⁻², as quoted in “Synthetic moissanite: a new diamond substitute”, Gems and Gemology volume 33, issue 4, winter 1997).

FIG. 1 is a flow diagram illustrating exemplary steps for making CVD single crystal diamonds. The following numbering corresponds to that of FIG. 1:
S1. A plurality of single crystal diamond substrates is located on a substrate carrier within a CVD reactor.
S2. Process gases are fed into the reactor. The process gases include a hydrogen-containing gas, a carbon-containing gas, and a nitrogen-containing gas. The relative quantities of these gases are such as to be stoichiometrically equivalent to a C₂H₂/H₂ ratio between 1% and 5% and a N₂/C₂H₂ ratio between 4 ppm and 60 ppm. Microwaves are used to generate a plasma from the gases.
S3. Single crystal CVD diamonds are grown on the surfaces of the plurality of single crystal diamond substrates at a temperature of between 750° C. and 1100° C. The growth is preferably performed as a single continuous and uninterrupted CVD synthesis cycle or “run”.
S4. The resultant plurality of single crystal CVD diamonds are annealed at a temperature of between 1700° C. and 2200° C. The annealing is preferably performed under diamond-stabilising pressure.

The grown single crystal diamonds may be cut and polished to form a gem, which may include at least a portion of the single crystal diamond substrate. The cutting and polishing may be performed either before or after the annealing.

While this invention has been particularly shown and described with reference to embodiments, it will be understood by those skilled in the art that various changes in form and detail may be made without departing from the scope of the invention as defined by the appended claims. For example, a skilled person will appreciate that the single crystal diamond material disclosed herein, with its combination of low and controllable optical absorption, low birefringence, high purity aside from deliberately introduced nitrogen, low fluorescence, relatively large size, and ability to be produced economically in volume, as described within the scope of the appended claims, will have a variety of potential applications. These may not necessarily be consumer-focused and could include uses for optical, thermal, or mechanical elements, or other technical products.

For example, the diamond may be used in mechanical applications such as wire drawing dies, graphical tools, stichels, and high pressure fluid jet nozzles, such as high pressure water jet nozzles.

Alternatively, the diamond is formed into an optical element. Exemplary optical elements include intracavity optical elements, high power transmission optical elements, Raman laser optical elements, etalons, and a Attenuated Total Reflection (ATR) optical elements. These can benefit from the low absorption and low birefringence that the diamond described herein displays. The high thermal conductivity of diamond makes the material particularly useful for applications where heat spreading is required.

1. A CVD single crystal diamond having the following characteristics:
a smallest linear dimension of no less than 3.5 mm;
a concentration of single substitutional nitrogen atoms in their neutral charge state (Nₛ⁰), as measured by EPR, of between 20 and 250 ppb;
a hue angle, h_{ab}, between 75 and 135°;
wherein the CVD single crystal diamond further comprises H₃ (NVN⁰) centres.

2. The CVD single crystal diamond according to claim 1, wherein the CVD single crystal diamond has a total concentration of nitrogen vacancy centres in their neutral and negative charge states (NV⁰ and NV⁻) less than the greater of 0.1 times the Nₛ⁰ concentration or 10 ppb.

3. The CVD single crystal diamond according to claim 1, wherein the CVD single crystal diamond has a hue angle, h_{ab}, selected from any of between 85 and 125°, between 9° and 120° and between 95 and 115°.

4. The CVD single crystal diamond according to claim 1, wherein the CVD single crystal diamond displays SiV luminescence, quantified by a ratio of a total peak area of the SiV zero-phonon lines to a peak area of the first-order diamond Raman signal in a photoluminescence measurement performed at a temperature of 77 K using an excitation wavelength of 660 nm, selected from any of less than 0.5; less than 0.1; less than 0.05; and less than 0.01.

5. (canceled)

6. The CVD single crystal diamond according to claim 1, wherein a total volume of the single crystal CVD diamond material is selected from any of at least 60 mm³, at least 80 mm³ and at least 100 mm³.

7. (canceled)

8. The CVD single crystal diamond according to claim 1, in the form of a gem, and having a colour grade, following the Gemological Institute of America (GIA) scale and methodology, that is selected from any of D, E and F when the Nₛ⁰ concentration is between 20 and 100 ppb, and selected from any of G, H, I, and J when the Nₛ⁰ concentration is between 80 and 250 ppb.

9. The CVD single crystal diamond according to claim 1, in the form of a gem, and having a clarity grade, following the Gemological Institute of America (GIA) scale and methodology, that is selected from any of VS₂, VS₁, VVS₂, VVS₁, IF, and FL.

10. (canceled)

11. The CVD single crystal diamond according to claim 1, wherein the CVD single crystal diamond displays a (NV⁰+NV⁻)/H3 ratio of less than 30 in a photoluminescence measurement performed at a temperature of 77 K using an excitation wavelength between 455 and 459 nm, where each of the NV⁰, NV⁻, and H3 defects is quantitated by the peak area ratio of its zero-phonon line to the first-order diamond Raman signal.

12. The CVD single crystal diamond according to claim 1, wherein the CVD single crystal diamond displays a N3/H3 ratio of less than 0.1 in a photoluminescence measurement performed at a temperature of 77 K using excitation wavelengths of between 323 and 327 nm for N3 and between 455 and 459 nm for H3, where each of the defects is quantitated by the peak area ratio of its zero-phonon line to the first-order diamond Raman signal.

13. The CVD single crystal diamond according to claim 1, which is formed into a mechanical element.

14. The CVD single crystal diamond according to claim 1, which is formed into an optical element.

15. The CVD single crystal diamond according to claim 11, wherein the optical element is selected from any of an intracavity optical element, a high power transmission optical element, a Raman laser optical element, an etalon, and an Attenuated Total Reflection, ATR, optical element.

16. A method of making a plurality of single crystal CVD diamonds according to claim 1, the method comprising:
locating a plurality of single crystal diamond substrates on a substrate carrier within a chemical vapour deposition reactor;
feeding process gases into the reactor, the process gases including a hydrogen-containing gas, a carbon-containing gas, and a nitrogen-containing gas, where the relative quantities of these gases are such as to be stoichiometrically equivalent to a C₂H₂/H₂ ratio between 1% and 5% and a N₂/C₂H₂ ratio between 4 ppm and 60 ppm;
growing the plurality of single crystal CVD diamonds on the surfaces of at least some of the plurality of single crystal diamond substrates at a temperature of between 750° C. and 1100° C.; and
annealing at least some of the resultant plurality of single crystal CVD diamonds at a temperature of between 1700° C. and 2200° C.

17. (canceled)

18. The method according to claim 16, wherein the CVD synthesis provides a volumetric growth rate for single-crystal diamond material grown in a single reactor that is selected from any of at least 10 mm³/h, at least 20 mm³/h, at least 30 mm³/h, at least 40 mm³/h, and at least 50 mm³/h.

19. The method according to claim 16, wherein the annealing is performed under diamond-stabilising pressure.

20. The method according to claim 16, wherein the total volume of single-crystal diamond treated in a single annealing operation is selected from any of at least 500 mm³, at least 1000 mm³, at least 1500 mm³, and at least 2000 mm³.

21. The method according to claim 16, wherein the carbon-containing and hydrogen-containing process gases are provided in quantities stoichiometrically equivalent to a C₂H₂/H₂ ratio in a range selected from any of 2% to 4%; and 2.5% to 3.5%.

22. The method according to claim 16, wherein the nitrogen-containing and carbon-containing process gases are provided in quantities stoichiometrically equivalent to a N₂/C₂H₂ ratio in a range selected from any of 5 ppm to 20 ppm; 10 ppm to 50 ppm; 7 ppm to 15 ppm; and 15 ppm to 35 ppm.

23. The method according to claim 16, wherein the plurality of CVD single crystal diamonds are grown at a temperature selected from any of between 800° C. and 1050° C.; between 800° C. and 950° C.; and between 825° C. and 925° C.

24. The method according to claim 16, wherein the annealing is performed at a temperature selected from any of between 1750° C. and 2100° C.; between 1800° C. and 2000° C.; and between 185° and 1950° C.

25. (canceled)
